(19) United States
(12) Patent Application Publication
(10) Pub. No.: US 2009/0237377 A1
(43) Pub. Date: Sep. 24, 2009

(54) ELECTRONIC DEVICE, HANDHELD DEVICE AND STYLUS

(75) Inventors: Hung-Yuan Lai, Taipei City (TW); Huang-Lin Lee, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: COMPAL ELECTRONICS, INC., Taipei City (TW)

(21) Appl. No.: 12/357,361

(22) Filed: Jan. 21, 2009

(30) Foreign Application Priority Data
Mar. 20, 2008 (TW) 97109897

(51) Int. Cl. G06F 3/033; H05K 7/20

(52) U.S. Cl. 345/179; 361/679.46

(57) ABSTRACT

An electronic device having a device case, a first electrode, and a modular accessory is provided. The first electrode is located in the device case. The modular accessory is removably assembled to the device case, and includes an accessory case, a second electrode, and a fan. When the accessory case is assembled to the device case and the second electrode contacts the first electrode, the fan is driven to discharge hot air from the device case

### CROSS-REFERENCE TO RELATED APPLICATION

This application claims the priority benefit of Taiwan application serial no. 97109897, filed on Mar. 20, 2008. The entirety of the above-mentioned patent application is hereby incorporated by reference herein and made a part of specification.

### BACKGROUND OF THE INVENTION

1. Field of the Invention

The present invention relates to an electronic device with a modular accessory having a fan for discharging hot air within a device case of the electronic device.

2. Description of Related Art

Following rapid advancing of the personal computer fabrication technology, many types of mobile computers have been developed on the basis of desk-top computers which originally need to be placed on a table to use. These mobile computers include, for example, notebook computers, personal digital assistants (PDAs), pocket PCs, and the like. However, these mobile computers all have a heat dissipation issue due to the small room in their cases.

The heat generated by the micro-control-units (MCU) of the mobile computers must be timely removed, or the temperature of the MCU continuously rises to exceed its normal operating temperature range. However, the amount of heat generated by the MCU increases with the increase in the operating speed of the MCU. Therefore, the temperature of the MCU must be lowered to maintain the normal operation of the MCU.

The mobile computers tend to be light, thin and small, and the operating speed of the MCUs of the mobile computers is being continuously increased. Therefore, due to the limited room in the computer case of the mobile computers, how to address the heat dissipation issue has been a great challenge.

### SUMMARY OF THE INVENTION

Accordingly, the present invention is directed to an electronic device with a modular accessory. The modular accessory includes a fan for discharging hot air from a device case of the electronic device.

The present invention is also directed to a handheld device with a stylus. The stylus includes a fan for discharging hot air from a device case of the handheld device.

The present invention is also directed to a stylus having a fan for discharging hot air from a device case.

The present invention provides an electronic device including a device case, a first electrode, and a modular accessory. The first electrode is located in the device case. The modular accessory is removably assembled to the device case, and includes an accessory case, a second electrode, and a fan. When the accessory case is assembled to the device case and the second electrode contacts the first electrode, the fan is driven to discharge hot air from the device case.

According to one embodiment of the present invention, the device case has a receiving space and the modular accessory is disposed in the receiving space.

According to one embodiment of the present invention, the accessory case has an air inlet in communication with the receiving space and an air outlet in communication with the air inlet, and the fan is located between the air inlet and the air outlet.

According to one embodiment of the present invention, the device case has an opening, the accessory case has an air inlet adapted for communication with the opening and an air outlet in communication with the air inlet, and the fan is located between the air inlet and the air outlet.

The present invention provides a handheld device including a device case, a first electrode, and a stylus. The device case has a receiving space. The first electrode is located in the device case. The stylus is removably assembled to the device case. The stylus includes a stylus case, a fan, and a second electrode. The stylus case is adapted to be assembled into the device case, and has at least one air inlet adapted for communication with the receiving space and at least one air outlet in communication with the air inlet. The fan is located in the stylus case and between the air inlet and the air outlet. The second electrode is connected to the fan and adapted to contact the first electrode. When the stylus case is assembled into the device case and the second electrode contacts the first electrode, the fan is driven to discharge hot air from the device case.

According to one embodiment of the present invention, the stylus case includes a front section and a rear section, and the fan is located between the front section and the rear section.

According to one embodiment of the present invention, the first electrode includes a pair of electrode spring plates adapted for clamping the second electrode.

According to one embodiment of the present invention, the device case includes a locking member adapted for locking the stylus in the device case.

The present invention provides a stylus suitable for a handheld device. The handheld device includes a device case and a first electrode located in the device case. The device case has a receiving space. The stylus includes a stylus case, a fan, and a second electrode. The stylus case is adapted to be assembled into the device case, and has at least one air inlet adapted for communication with the receiving space and at least one air outlet in communication with the air inlet. The fan is located in the stylus case and between the air inlet and the air outlet. The second electrode is connected to the fan and adapted to contact the first electrode. When the stylus case is assembled into the device case and the second electrode contacts the first electrode, the fan is driven to discharge hot air from the device case.

According to one embodiment of the present invention, the stylus case includes a front section and a rear section, and the fan is located between the front section and the rear section.

According to one embodiment of the present invention, the first electrode includes a pair of electrode spring plates adapted for clamping the second electrode.

The modular accessory having the fan is used in embodiments of the present invention. When the modular accessory is assembled to the device case and the first electrode contacts the second electrode, the fan can be driven by the circuit board to discharge the hot air from the device case, thereby lowering the operating temperature of the electronic device.

In order to make the aforementioned and other features and advantages of the present invention more comprehensible, embodiments accompanied with figures are described in detail below.

### BRIEF DESCRIPTION OF THE DRAWINGS

FIG. 1A is an exploded view of an electronic device according to one embodiment of the present invention.

FIG. 1B is an assembled view of the electronic device of FIG. 1A.

FIG. 2A is an exploded view of an electronic device according to another embodiment of the present invention.

FIG. 2B is an assembled view of the electronic device of FIG. 2A.

FIG. 3A illustrates a handheld device according to another embodiment of the present invention.

FIG. 3B is an exploded view of part of the handheld device of FIG. 3A.

FIG. 3C is an assembled view of the part of the handheld device of FIG. 3B.

### DESCRIPTION OF THE EMBODIMENTS

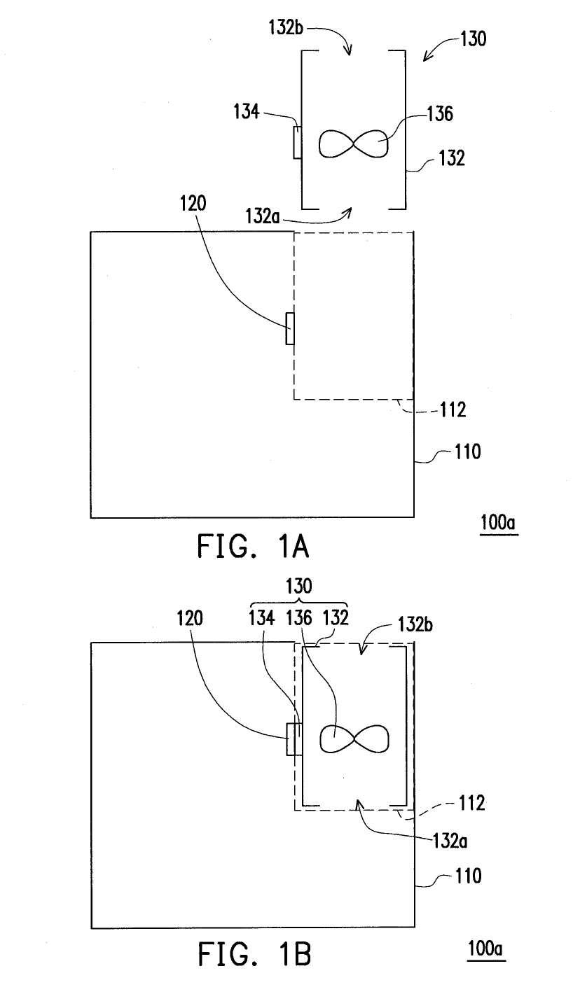

FIG. 1A is an exploded view of an electronic device according to one embodiment of the present invention. FIG. 1B is an assembled view of the electronic device of FIG. 1A. Referring to FIGS. 1A and 1B, in the present embodiment, the electronic device 100a includes a device case 110, a first electrode 120, and a modular accessory 130. The first electrode 120 is disposed within the device case 110, and the modular accessory 130 is removably assembled to the device case 110.

Specifically, the device case 110 has a receiving space 112 and the modular accessory 130 is disposed in the receiving space 112. In the present embodiment, the modular accessory 130 includes an accessory case 132, a second electrode 134, and a fan 136. The accessory case 132 has an air inlet 132a in communication with the receiving space 112, and an air outlet 132b in communication with the air inlet 132a. The fan 136 is disposed between the air inlet 132a and the air outlet 132b.

When the accessory case 132 is assembled into the receiving space 112 of the device case 110 and the second electrode 134 contacts the first electrode 120, the fan 136 is driven to discharge hot air from the device case 110.

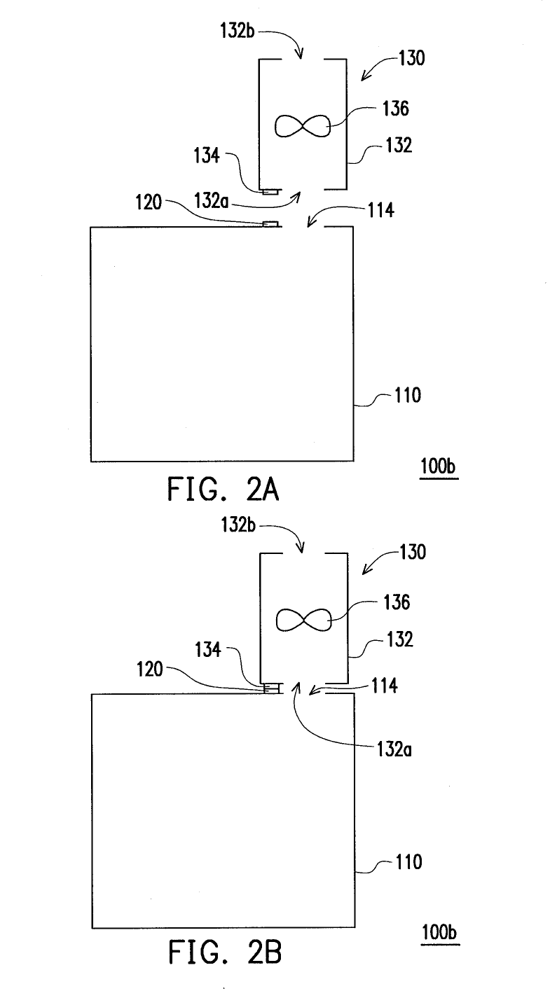

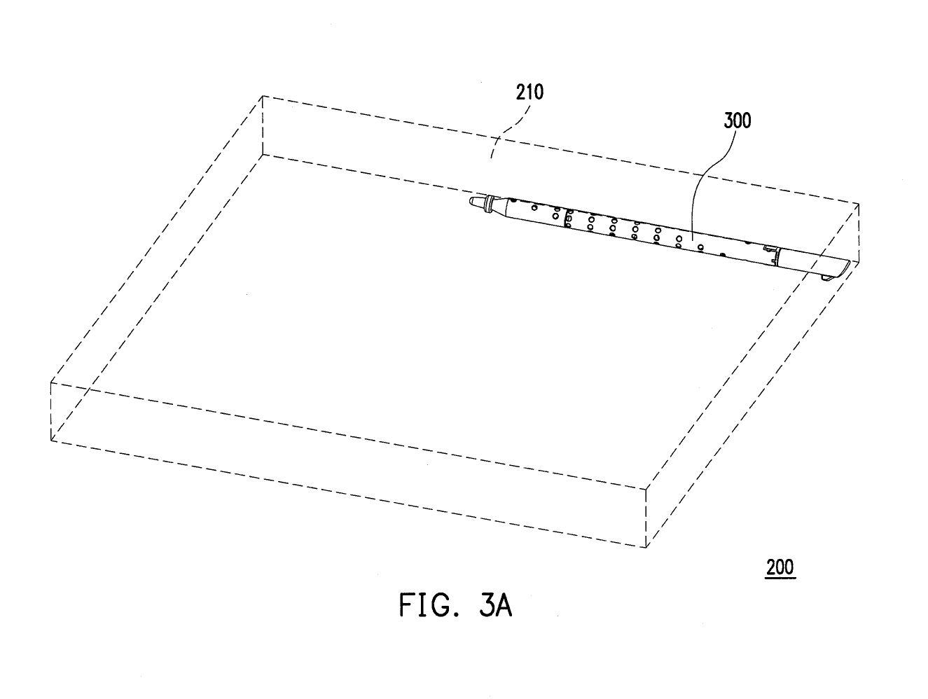

FIG. 2A is an exploded view of an electronic device according to another embodiment of the present invention, and FIG. 2B is an assembled view of the electronic device of FIG. 2A. Referring to FIGS. 2A and 2B, the electronic device 100b of FIG. 2A is similar to the electronic device 100a of FIG. 1 A except that the device case 110 has an opening 114, the accessory case 132 has an air inlet 132a adapted for communication with the opening 114 and an air outlet 132b in communication with the air inlet 132a, and the fan 136 is disposed between the air inlet 132a and the air outlet 132b.

When the accessory case 132 is assembled to the device case 110 and the second electrode 134 contacts the first electrode 120, the fan 136 is driven to discharge hot air within the device case 110.

In brief, the modular accessory 130 having the fan 136 is used in the embodiments described above. When the modular accessory 130 is assembled to the device case 110 and the first electrode 120 contacts the second electrode 134, the fan 136 is driven to discharge hot air within the device case 110, thereby lowering an operating temperature of the electronic device 100a or electronic device 100b.

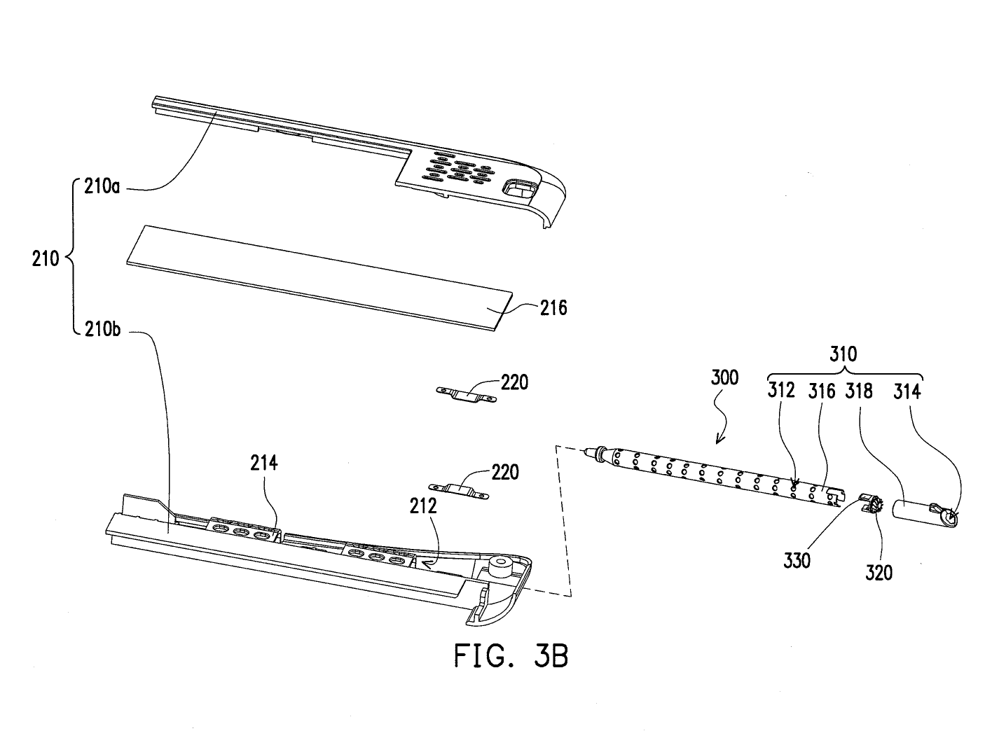

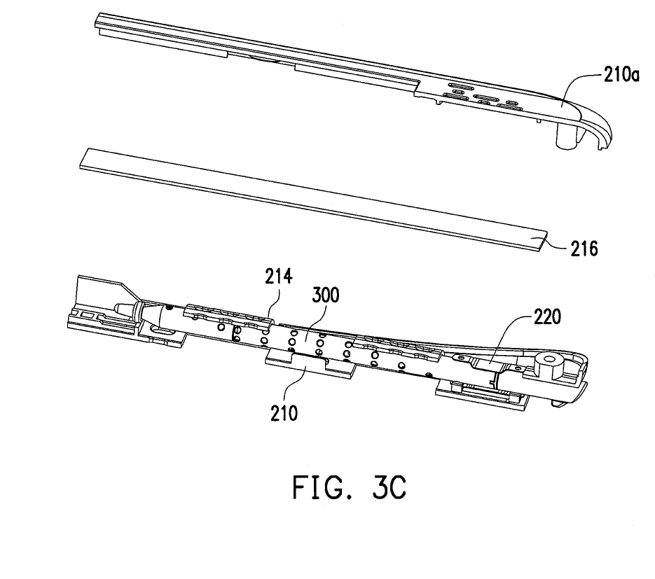

FIG. 3A illustrates a handheld device according to one embodiment of the present invention, FIG. 3B is an exploded view of part of the handheld device of FIG. 3A, and FIG. 3C is an assembled view of the part of the handheld device of FIG. 3B. Referring to FIG. 3A and FIG. 3B, in the present embodiment, the handheld device 200 is, for example, a PDA, a pocket PC or a smart phone. The handheld device 200 includes a device case 210, a pair of first electrodes 220, and a stylus 300. The number of the first electrodes 220 could be one or more depending on the product design. The present embodiment employs two first electrodes 220 but this is not intended to limit the present invention.

Referring to FIG. 3B and FIG. 3C, the device case 210 has a receiving space 212, an upper device case part 210a, a lower device case part 210b, and a circuit board 216. The first electrodes 220 are disposed between the lower device case part 210b and the circuit board 216. The stylus 300 is removably assembled to the lower device case part 210b.

Specifically, the stylus 300 includes a stylus case 310, a fan 320, and a pair of second electrodes 330. The stylus case 310 includes a front section 316 and a rear section 318. The fan 320 is disposed between the front section 316 and the rear section 318 and connected to the second electrodes 330. The stylus case 310 is adapted to be assembled into the device case 210b. The stylus case 310 has at least one air inlet 312 adapted for communication with the receiving space 212 and at least one air outlet 314 in communication with the inlet 312. The number of the second electrodes 330 could be one or more depending on the product design. The present embodiment employs two second electrodes 330 but this is not intended to limit the present invention.

In particular, in the present embodiment, the fan 310 is disposed between the front section 316 and the rear section 318 and between the air inlet 312 and the air outlet 314. In addition, the air inlets 312 are generally spirally arranged in the front section 316 of the stylus 310. When the fan 320 is driven to discharge the hot air from the device case 210, these air inlets 312 can reduce loss of performance of the fan 320.

In general, the basic function of the stylus 300 is to be a supplement to and a substitution of user's finger to touch a display panel while avoiding damage to the display panel. It is to be noted that, in the present embodiment, the fan 320 is disposed in the stylus case 310 of the stylus 300 without changing the basic function and structure of the stylus 300. Therefore, when the stylus 300 is assembled within the device case 210 and the handheld device 200 is in an operating state, the fan 320 in the stylus 300 is able to discharge the hot air from the device case 210 to lower the operating temperature of the handheld device 200.

Referring to FIGS. 3B and 3C, the second electrodes 330 are adapted for contact with the first electrodes 220, respectively. The first electrodes 220 are, for example, a pair of electrode spring plates for clamping the second electrodes 330. When the circuit board 216 is electrically connected with the first electrodes 220 and the pair of first electrodes 220 respectively contacts the pair of second electrodes 330, the fan 320 can be driven to discharge the hot air from the device case 210.

Besides, the device case 210b may include a plurality of locking members 214 for locking the stylus 300 in the device case 210b. When the stylus case 310 is assembled into the device case 210b and the pair of second electrodes 330 respectively contacts the pair of first electrodes 220, the fan 320 can be driven to discharge the hot air from the device case 210.

In summary, the stylus includes a fan disposed therein. When the stylus is assembled into the device case and the pair of second electrodes respectively contacts the pair of first electrodes, the fan can be driven by the circuit board to discharge the hot air from the device case. Therefore, the operating temperature of the handheld device can be lowered by driving the fan to discharge the hot air the device case. Besides, the fan is disposed in the stylus without changing the basic function and structure of the stylus. Therefore, when drawn out of the device case, the stylus still maintains its basic function.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic apparatus comprising:
a device case;
a first electrode located in the device case; and
a modular accessory removably assembled to the device case and comprising an accessory case, a second electrode, and a fan, wherein when the accessory case is assembled to the device case and the second electrode contacts the first electrode, the fan is driven to discharge hot air form the device case.

2. The electronic apparatus according to claim 1, wherein the device case has a receiving space and the modular accessory is disposed in the receiving space.

3. The electronic apparatus according to claim 2, wherein the accessory case has an air inlet in communication with the receiving space and an air outlet in communication with the air inlet, and the fan is located between the air inlet and the air outlet.

4. The electronic apparatus according to claim 1, wherein the device case has an opening, the accessory case has an air inlet adapted for communication with the opening and an air outlet in communication with the air inlet, and the fan is located between the air inlet and the air outlet.

5. A handheld device comprising:
a device case having a receiving space;
a first electrode located in the device case; and
a stylus removably assembled to the device case, the stylus comprising:
a stylus case adapted to be assembled into the device case, and having at least one air inlet adapted for communication with the receiving space and at least one air outlet in communication with the air inlet;
a fan located in the stylus case and between the air inlet and the air outlet; and
a second electrode connected to the fan and adapted to contact the first electrode,
wherein when the stylus case is assembled into the device case and the second electrode contacts the first electrode, the fan is driven to discharge hot air from the device case.

6. The handheld device according to claim 5, wherein the stylus case includes a front section and a rear section, and the fan is located between the front section and the rear section.

7. The handheld device according to claim 5, wherein the first electrode includes a pair of electrode spring plates adapted for clamping the second electrode.

8. The handheld device according to claim 5, wherein the device case includes a locking member adapted for locking the stylus in the device case.

9. A stylus adapted for use in a handheld device, the handheld device comprising a device case and a first electrode located in the device case, the device case having a receiving space, the stylus comprising:
a stylus case adapted to be assembled into the device case, and having at least one air inlet adapted for communication with the receiving space and at least one air outlet in communication with the air inlet;
a fan located in the stylus case and between the air inlet and the air outlet; and
a second electrode connected to the fan and adapted to contact the first electrode,
wherein when the stylus case is assembled into the device case and the second electrode contacts the first electrode, the fan is driven to discharge hot air from the device case.

10. The stylus according to claim 9, wherein the stylus case includes a front section and a rear section, and the fan is located between the front section and the rear section.

11. The stylus according to claim 9, wherein the first electrode includes a pair of electrode spring plates adapted for clamping the second electrode.
